(19) United States
(12) Patent Application Publication
(10) Pub. No.: US 2003/0053560 A1
(43) Pub. Date: Mar. 20, 2003

(54) Radio station comprising a receiver for receiving data transmitted along various paths and receiving method implemented in such a receiver

(76) Inventor: Olivier Paviot, Le Mans (FR)

Correspondence Address: U.S. Philips Corporation, 580 White Plains Road, Tarrytown, NY, 10591, US

(21) Appl. No.: 10/180,404

(22) Filed: Jun. 26, 2002

(30) Foreign Application Priority Data
Jun. 26, 2001 (FR) 0108418

(51) Int. Cl. H03K 9/00; H04L 27/06

(52) U.S. Cl. 375/316

(57) ABSTRACT

This apparatus comprises a receiver called Rake receiver comprising delay lines (L1 to LN) for processing data transmitted in symbols along a plurality of paths (T1 to TN), a symbol processing circuit (40) which produces the information from said delay circuits, followed by an alignment module (30). The processing circuit (40) processes the symbol that is predominantly found in delay circuits. In this way its value is estimated better.

The invention relates to a radio station comprising a receiver for receiving data transmitted in symbols along a plurality of paths, the receiver comprising a plurality of delay circuits for receiving the data coming from each of the paths and a processing circuit which produces information from said delay circuits.

The invention also relates to a receiving method implemented in such a receiver.

The invention finds interesting applications for stations operating in the CDMA mode. In this mode the data coming from the transmitter and received along paths of different duration are processed. The receivers known by the name of Rake receivers operate in this mode and process the data and this information while taking account of a plurality of these paths. Each of these processed paths requires a delay line.

A station of this type is known from U.S. Pat. No. 5,537,438. This document relates to an improvement of the reception of information blocks by the use of equalization methods.

The invention proposes a station of the type mentioned in the opening paragraph which also permits to improve the reception of data by using another method than the equalization method.

Such a station is characterized in that the processing circuit processes the symbol that is predominantly found in the delay circuits.

Thus, by the measure recommended by the invention, the processing which follows these delay circuits produces a better result with the symbol to be processed because this symbol that is represented most contributes to the estimation.

These and other aspects of the invention are apparent from and will be elucidated, by way of non-limitative example, with reference to the embodiment(s) described hereinafter.

In the drawings:

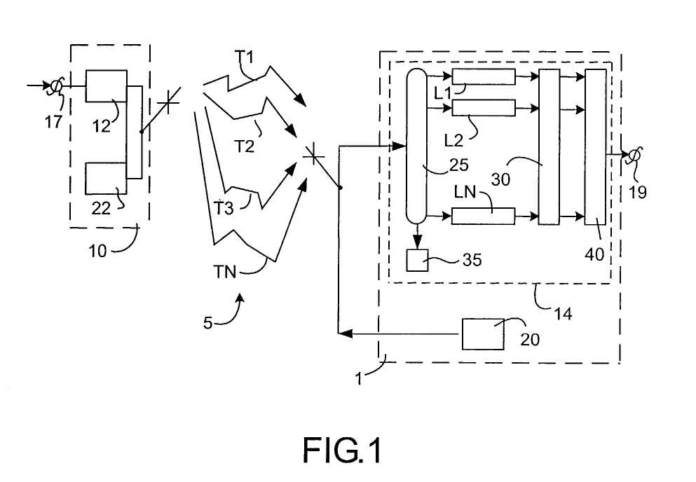

FIG. 1 shows an apparatus in accordance with the invention which forms part of a transmission system,

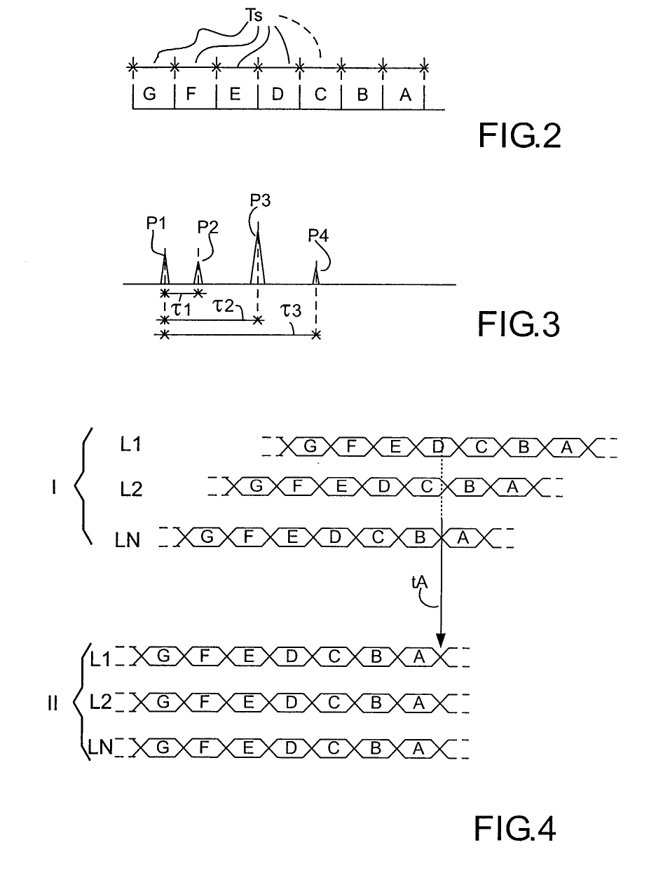

FIG. 2 shows a sequence of symbols to be transmitted,

FIG. 3 shows the curve of a correlation peak obtained at the receiver along various propagation paths,

FIG. 4 shows the effect obtained by an alignment module,

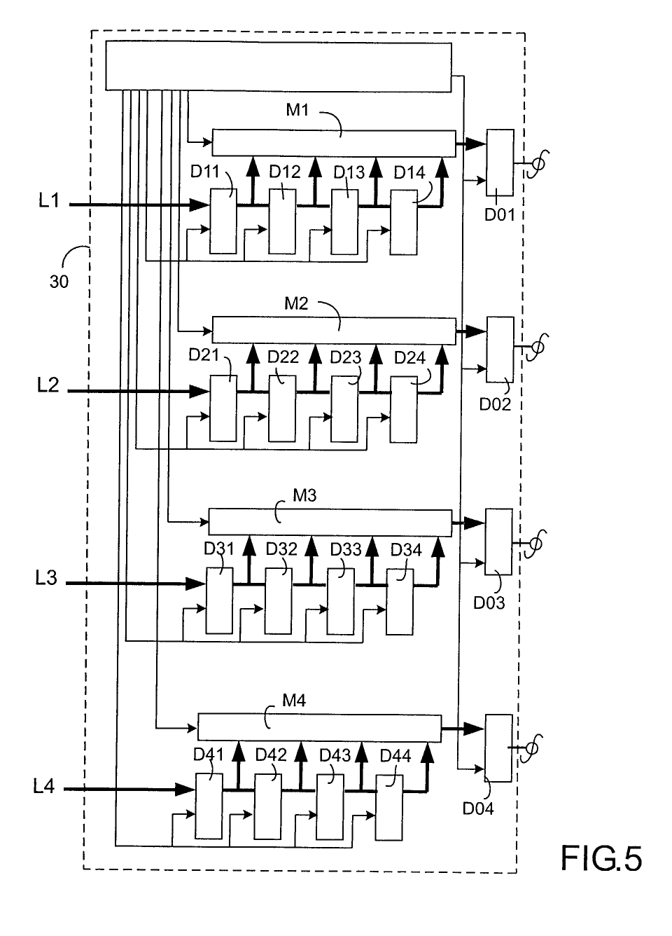

FIG. 5 shows the arrangement of the delay lines,

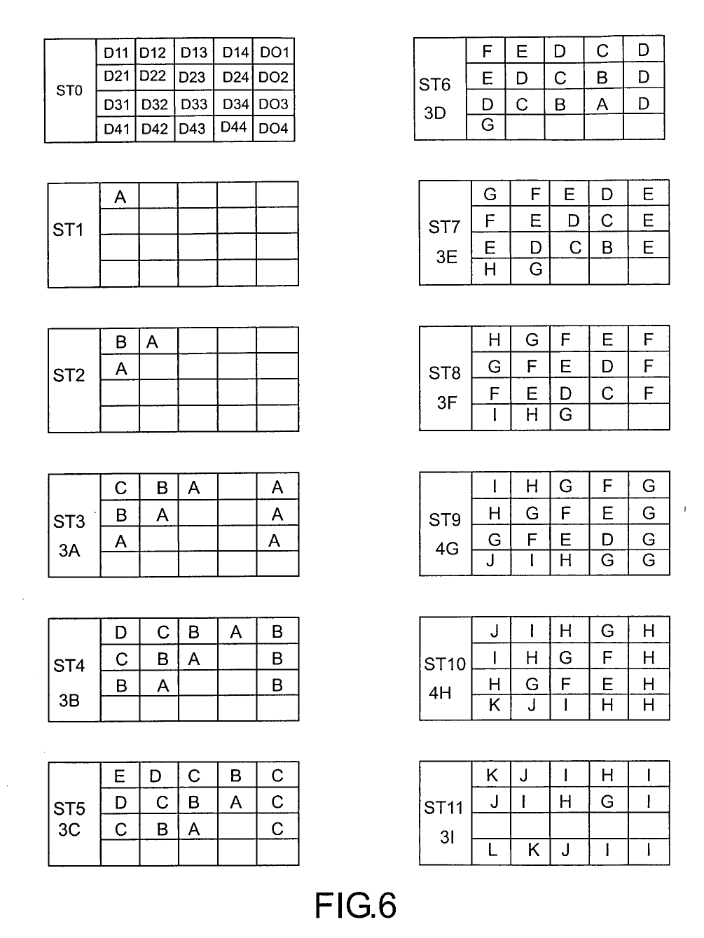

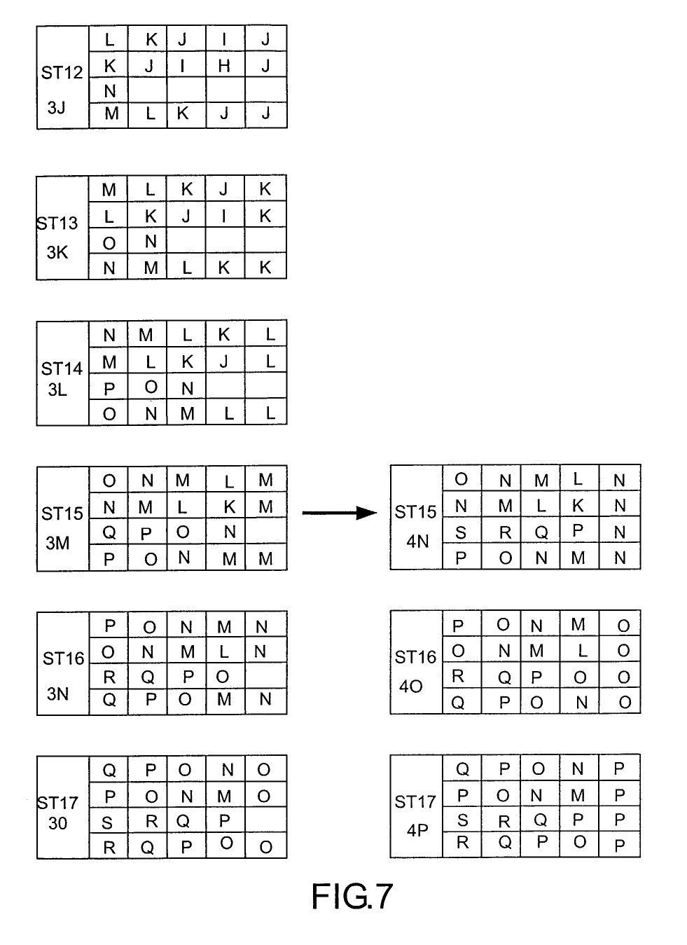

FIGS. 6 and 7 show the evolution of the occupancy of these lines in a first case,

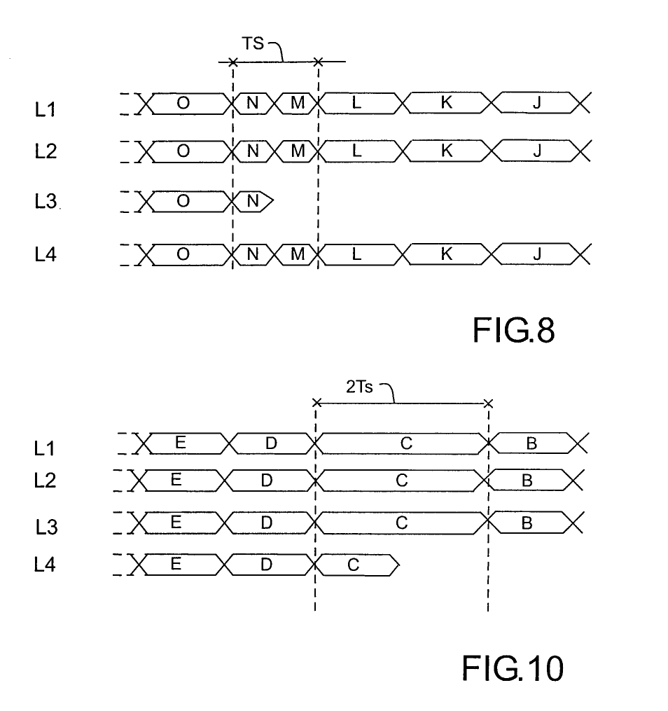

FIG. 8 shows the breakdown in the timing in the first case,

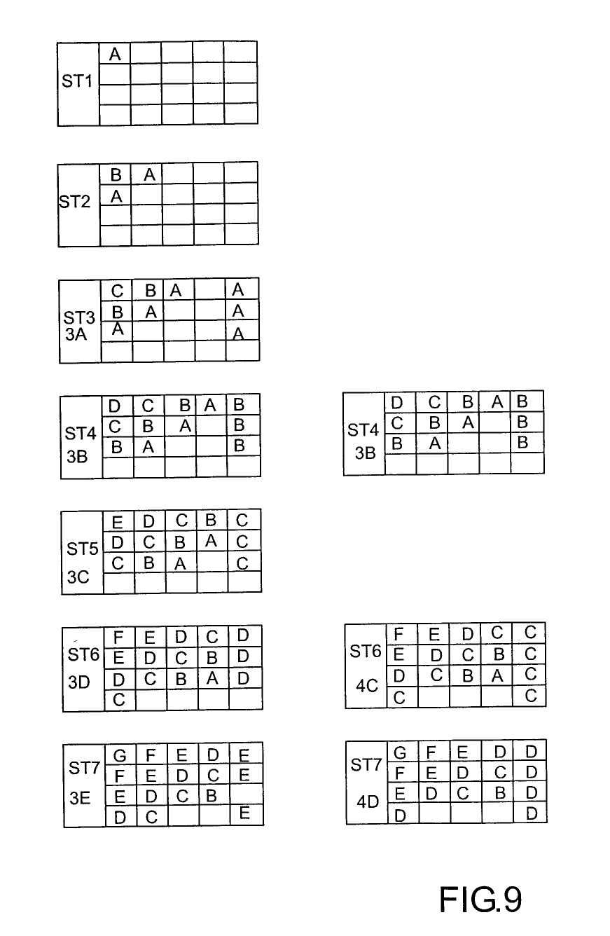

FIG. 9 shows the evolution of the occupancy of these lines in a second case,

FIG. 10 shows the breakdown of the timing in the second case.

In FIG. 1 is shown an apparatus 1 according to the invention which forms part of a system 5. In this Figure is represented a second apparatus 10 with which the apparatus 1 communicates along a code spread spectrum link. The link between the two stations transmits symbols of which the stream is constant. Each transmitted symbol is formed by a binary element chopped by a spread spectrum code in the form of chips. The transmission which takes place, for example, from the transmitting part 12 of the station 10 to the receiving part 14 of the station 1, takes a multiplicity of paths. Thus data applied to an access terminal 17 of the transmitting part 12 are found back at an output access terminal 19 of the receiving part 14. Only the larger paths are considered: that is to say, the paths T1, T2, T3, . . . , TN. These various paths form a multipath propagation channel (T1, T2, . . . , TN) of which the number N and the characteristics vary with time. Consequently, the station 1 receives a certain number of replicas of the same stream of transmitted symbols but which are shifted with time. The receiving part 14 processes these N paths. Conversely, the station 1 comprises a transmitting part 20 and the station 10 a receiving part 22. In the following only the transmission from the station 10 to the station 1 will be considered, which implies the various paths T1 to TN cited above. For this purpose, the receiving part 14 has N lines L1, L2, . . . , LN, or a delay circuit, which are previously synchronized by the path module 25 which detects the paths and synchronizes them so as to process the N paths present in the propagation channel independently. Within the framework of the example described, each of these lines carries out a decorrelation operation of the path with which it is synchronized. At the output of these N lines a time-dependent alignment module 30 aligns the output signals of the lines L1, L2, . . . , LN as a function of time, so that all the lines of the system are mutually synchronized.

The operation of the module 25 is explained with the aid of FIGS. 2 and 3. FIG. 2 shows a sequence of transmitted symbols which appear in the order A, B, C, D, . . . , F, G, . . . , while the symbols have a duration Ts. Since a code spread spectrum is used (CDMA) a correlation of these symbols effected with these data causes correlation peaks to occur of which the number depends on the propagation paths. This is represented in FIG. 3. After a first correlation peak P1 a second peak P2 is received after a propagation time τ1, a peak P3 after a propagation time τ2 and a peak P4 after a propagation time τ3. With the various propagation times it is possible to establish a table of the symbols entered in the various delay lines L1 to LN. For example, if the sequence shown in FIG. 2 is considered, the symbol A is taken as a reference. This symbol, which is the first signal that has given the correlation peak P1, has returned to line L1, the symbol to return to line Li depending on the time that has elapsed since the appearance of the peak P1.

If TS<τi<2Ts, the symbol stored in the line will be B.

If 2TS<τi<3Ts the symbol stored in the line will be C, and so on.

A table 35 (FIG. 1) permits to establish the sequences of symbols contained in the lines L1 to LN.

According to the invention a symbol processing module 40 is provided which permits to resolve the problem of limits associated with this module. Symbols to be estimated as a function of their number which is present in the delay lines L1 to LN will be taken into account.

Definition of the Problem

FIG. 4 shows in I the input signals of the lines L1 to LN. These signals show various data formed by ordered symbols referenced: A, B, C, D, E, F, G, . . . which appear at the input of the module 30. Reference II shows the signals at the output of the alignment module 30.

Each line independently processes a received path and finds back this same symbol sequence which, however, is shifted with time. Actually, in FIG. 4 at I, while line LN has received the symbol A, the line L1 already processes the symbol D. Thus, to correctly carry out the final alignment process of all the paths (lines), each symbol is to be stored on each line until the path that delays most has been processed in its turn. Once the last path has been processed for a given symbol, the output of the alignment module is activated for this symbol and the synchronous alignment process may be carried out. At II FIG. 4 illustrates this principle at instant tA for the symbol A which is validated at the output of the alignment module once it has been processed by the line LN.

During communication, the paths may appear or disappear at random following the propagation phenomena that are met. On the other hand, the appearance of a new path or the disappearance of an old path may occur before, between or delayed relative to the other paths already used by the system.

In the following only 4 delay lines will be mentioned for clarity of the description.

The alignment module shown in FIG. 5 permits to process the effects of the appearing or disappearing paths better. It is in the form of:

16 banks of shift registers [D11-D44] used for delaying the signals coming from the outputs of each line,

4 bus multiplexers which permit to validate at the output of the module the 4 signals corresponding to the same symbol (for example: 4A, 4B, . . .).

1 management module for managing the multiplexers and banks of shift registers.

The number of shift register banks for each line indicates the number of symbols which can be stored in a memory and, consequently, the maximum delay which may exist between the first and last paths processed. This number is fixed during the design of the system and is thus to be established as a function of the propagation conditions envisaged for the channel.

It is to be noted that each register bank [D11, . . . , D44; D21, . . . , D24; D31, . . . , D34; D41, . . . , D44] is controlled independently for each line, whereas the register banks [D01, . . . , D04] are controlled synchronously for all the lines.

The operation of this module is explained with the aid of an example.

The example explained in FIGS. 6 and 7 illustrates the operation of the alignment module; it permits to show the problems with the limits associated with this system and helps to describe the principle which forms the object of this invention.

In this Figure are represented the outputs of the register banks [D11, . . . , D44], as well as the outputs of the register banks [D01, . . . , D04] at the output of the alignment module. This is shown by the rectangle ST0. The various steps of the time-dependent course of the procedure are represented here by the steps from 1 to n referred to by the rectangles ST1 to STn, respectively.

The selected configuration is that of 4 register banks per line and 4 independent lines (N=4). At the start of the process only 3 paths are present in the propagation channel.

At step 1 the first symbol A is received on the first line; it will not be validated at the output of the alignment module until step 3, which corresponds to the arrival of this same symbol A on the third and last line. The three As (3A) are then sent to the symbol processing module 40.

At step 4 the three Bs are validated at the output of the module and then the three Cs at step 5. At step 6 the 4^{th} line is activated on a new path arriving before the 3 already being processed. This new path is represented by the appearance of the symbol G on the last line. It should be noted that the first line only processes a symbol F. The 4^{th} path is only taken into account at step 9 when the four Gs are activated on the output of the alignment module.

At step 10 the four Hs are validated at the output of the module.

At step 11 the 3^{rd} path disappears; it is replaced in step 12 (FIG. 7) by a new path which appears once more before the other three already processed. The observation of the steps 13 to 17 of FIG. 7 shows us when it becomes possible to use this path if the process that has just been described is retained. In fact, the sequence of the symbols obtained will always remain 3K, 3L, 3M, 3N, 3O . . . instead of 3K, 3L, 3M, 4N, 4O.

Explanation of the Problem and Presentation of the Solution Adopted—Double Decision

The problem shown here is a problem to the limits associated with any system that possesses such a structure of register banks. In this example the problem comes from the fact that the fourth line is already aligned with a last register bank thus making it difficult to take a new path into account that arrives before the others. Therefore, when the presence of a register bank [Di5, . . . , D45] turns out to be necessary, it is however impossible to insert this additional register bank partly because of the inflexible nature of the system.

The method that has just been described now and forms the object of the present invention permits to resolve this problem without modifying the structure of the system and the sequence of the transmitted symbols, without changing the quality of the link.

This method results from an observation of the configurations of registers in FIG. 7. Actually, at step 15 it is perceived that in the register banks both 3Ms and 4Ns are disposed. At this instant, to ensure a stream of correct data, the decision is to be made about the 3Ms and not about the 4Ns. The idea of the invention is here to make a double decision, both on the 3Ms and on the 4Ns. At step 16 it then becomes possible to continue with 40s, after that 4Ps at step 17 and so on with a normal timing. The data stream may then be represented by FIG. 7. It is observed once more that this method is entirely based on the use of original data and does not alter the quality of the link at all.

FIG. 8 shows the breakdown of the timing. The symbols M and N are both processed in a single period TS.

Other Case of the Figure of the Edge Effect—Absence of Decision

FIG. 9 shows the same edge effect but applied to the case where the paths always appear after those already being processed. The first steps from 1 to 5 are identical with the preceding steps of FIG. 6. At step 6 a new path delayed relative to the paths already processed is taken into account. If no particular process is applied, this new path, neither this one, could not be validated at the output. There too the observation of the configuration of the register banks shows that at step 6 one obtains both 4Cs and 3Ds with the decision to be made on D. At step 7 one has 4Ds and 3Es with the decision on E. If no decision is made at step 6 it then becomes possible to recover the 4Ds at step 7 then 4Es at step 8 and so on. There too no alteration is made in the data stream which can now be represented by FIG. 10.

These apparent timing breakdowns often do not form an inconvenience for the circuits to be used. In fact, the symbols are estimated at the symbol processing circuit 40.

The method which is implemented in the invention may be summarized in the following manner via the following steps:

determination of the reception of the first symbol,

recording this first symbol in a first delay circuit,

recording N symbols received after this first symbol in each of the delay circuits,

examination of the majority of a symbol of a sequence at the appearance and/or disappearance of a path,

supply when using a symbol with a faster or slower timing as a function of said appearance/disappearance.

1. A radio station comprising a receiver for receiving data transmitted in symbols along a plurality of paths, the receiver comprising a plurality of delay circuits for receiving the data coming from each of the paths and a processing circuit which produces information from said delay circuits, characterized in that the processing circuit processes the symbol which is predominantly found in the delay circuits.

2. A radio station as claimed in claim 1, characterized in that the rank of a symbol of a sequence is defined by the time counted from the first received symbol onwards.

3. A radio station as claimed in one of the claims 1 or 2, characterized in that the majority decision is made during the appearance of a symbol due to a new path.

4. A radio station as claimed in one of the claims 1 to 3, characterized in that the majority decision is made during the disappearance of a symbol due to a new path.

5. A receiving method implemented in a station as claimed in one of the claims 1 to 4, characterized in that it comprises the following steps:
determination of the reception of the first symbol,
recording of this first symbol in a first delay circuit,
recording of N symbols received after this first symbol in each of the delay circuits,
examination of the majority of a symbol of a sequence at the appearance and/or disappearance of a path,
supply when using a symbol with a faster or slower timing as a function of said appearance/disappearance.
